(19) United States
(12) Patent Application Publication
(10) Pub. No.: US 2018/0325256 A1
(43) Pub. Date: Nov. 15, 2018

(54) Tabletop Attached by Removable Adhesives

(71) Applicants: David R. Hall, Provo, UT (US); William H. Reynolds, Orem, UT (US); Christopher Reymolds, Orem, UT (US); Joseph Blanch, Provo, UT (US); Nathan Davis, Bountiful, UT (US); Joe Fox, Spanish Fork, UT (US)

(72) Inventors: David R. Hall, Provo, UT (US); William H. Reynolds, Orem, UT (US); Christopher Reymolds, Orem, UT (US); Joseph Blanch, Provo, UT (US); Nathan Davis, Bountiful, UT (US); Joe Fox, Spanish Fork, UT (US)

(21) Appl. No.: 15/592,816

(22) Filed: May 11, 2017

(51) Int. Cl. A47B 13/00; A47B 3/06; A47B 13/08; A47B 21/06; A47B 27/00; B25H 1/02; A47B 33/00; A47B 37/00; A61G 13/10; A47B 13/04; A47B 13/06; A63F 11/00; C09J 201/00; C09J 183/04; C09J 189/00; H05K 5/00; G06F 3/041

(52) U.S. Cl. CPC A47B 13/003; A47B 2021/066; A47B 13/086; A47B 21/06; A47B 27/00; B25H 1/02; A47B 33/00; A47B 37/00; A61G 13/105; A47B 13/04; A47B 13/06; A63F 11/00; C09J 201/00; C09J 183/04; C09J 189/00; H05K 5/0017; G06F 3/041; A47B 3/06

(57) ABSTRACT

A table comprising a table base and a tabletop is disclosed. The table base comprises a top surface comprising one or more removable adhesives. The one or more removable adhesives adhere strongly when a force is applied in a horizontal direction and weakly when a force is supplied in a vertical direction. This prevents horizontal movement but allows vertical movement when a vertical force above an adhesion threshold is applied. The tabletop comprises a usable first side and a usable second side alternately mounted to the table base by means of the removable adhesives.

### FIELD OF THE INVENTION

This invention relates generally to tables with interchangeable tabletops. More particularly, we are interested in tabletops wherein both sides can be attached via removable adhesives.

### BACKGROUND

The table has been in use for the duration of recorded history in various forms. Tables are attached in many ways, such as bolts, clamps, and compression. However, tables are almost universally a one-sided device. One side is used for the tabletop, with the other side acting as the attachment point. This limits the table to having one surface. The ability to interchangeably utilize both sides of a tabletop without the need for attachment methods that leave holes, damage surfaces, or require extensive effort is needed.

United States patent publication number 2675288, to Usher teaches an interchangeable utility table. The table is convertible into a drawing desk. The present disclosure differs from this prior art disclosure in that the prior art disclosure uses hinges to modify the table surface, does not use removable adhesives, and doesn't allow for both sides of the tabletop to be attached to the base. This prior art disclosure is pertinent and may benefit from the devices disclosed herein and is hereby incorporated for reference in its entirety for all that it teaches.

United States patent publication number 20070039101, to Luginbuhl, et al., teaches specialized tabletops for medical imaging. Interchangeable specialized tabletops are provided, each constructed for specific uses, such as tomographic imaging. The present disclosure differs from this prior art disclosure in that the prior art disclosure does not attach the tabletops by removable adhesives and the two sides of each tabletop are not both able to be attached to the table base. This prior art disclosure is pertinent and may benefit from the devices disclosed herein and is hereby incorporated for reference in its entirety for all that it teaches.

United States patent publication number 5131105, to Harrawood, et al., teaches a patient support table. The table consists of interchangeable table supports and tabletops that are x-ray translucent. The present disclosure differs from this prior art disclosure in that the prior art disclosure does not attach the tabletops by removable adhesives and the two sides of each tabletop are not both able to be attached to the table base. This prior art disclosure is pertinent and may benefit from the devices disclosed herein and is hereby incorporated for reference in its entirety for all that it teaches.

United States patent publication number 1361420, to Van Dolsen teaches an operating table with interchangeable tabletops. The tabletops are held on with pins and only have one usable surface. The present disclosure differs from this prior art disclosure in that the prior art disclosure does not attach the tabletops by removable adhesives and the two sides of each tabletop are not both able to be attached to the table base. This prior art disclosure is pertinent and may benefit from the devices disclosed herein and is hereby incorporated for reference in its entirety for all that it teaches.

United States patent publication number 3241885, to Deaton, teaches modular furniture and components thereof. This is sectional furniture with multiple components that are usable together, including tabletops and table bases that can be mixed and matched. The present disclosure differs from this prior art disclosure in that the prior art disclosure attaches the tabletops by permanent adhesives and the two sides of each tabletop are not both able to be attached to the table base. This prior art disclosure is pertinent and may benefit from the devices disclosed herein and is hereby incorporated for reference in its entirety for all that it teaches.

United States patent publication number 5865129, to Samples, teaches a knock-down table consisting of a top frame and attachable legs. The top frame has a lip that can hold a tabletop. The present disclosure differs from this prior art disclosure in that the prior art disclosure does not attach the tabletops by removable adhesives and the two sides of each tabletop are not both able to be attached to the table base. This prior art disclosure is pertinent and may benefit from the devices disclosed herein and is hereby incorporated for reference in its entirety for all that it teaches.

United States patent publication number 1649388, to Frank, teaches a changeable-top table. The present disclosure differs from this prior art disclosure in that the prior art disclosure does not attach the tabletops to the table bases by removable adhesives and the two sides of each tabletop are not both able to be attached to the table base. This prior art disclosure is pertinent and may benefit from the devices disclosed herein and is hereby incorporated for reference in its entirety for all that it teaches.

United States patent publication number 8480091, to Florence, teaches a gaming table with interchangeable layouts. The present disclosure differs from this prior art disclosure in that the prior art disclosure does not attach the tabletops to the table bases by removable adhesives and the two sides of each tabletop are not both able to be attached to the table base. This prior art disclosure is pertinent and may benefit from the devices disclosed herein and is hereby incorporated for reference in its entirety for all that it teaches.

U.S. Pat. No. 6,823,804, to Arnell, teaches an interchangeable tabletop. The present disclosure differs from this prior art disclosure in that the prior art disclosure does not attach the tabletops to the table bases by removable adhesives and the two sides of each tabletop are not both able to be attached to the table base. This prior art disclosure is pertinent and may benefit from the devices disclosed herein and is hereby incorporated for reference in its entirety for all that it teaches.

United States patent publication number 2922505, to De Buigne, teaches an indexing table with an interchangeable rotatable table top with gear mechanisms that cause the table to rotate. The present disclosure differs from this prior art disclosure in that the prior art disclosure does not attach the tabletops to the table bases by removable adhesives and the two sides of each tabletop are not both able to be attached to the table base. This prior art disclosure is pertinent and may benefit from the devices disclosed herein and is hereby incorporated for reference in its entirety for all that it teaches.

U.S. Pat. No. 6,972,141, to Bries, et al., teaches a removable adhesive tape laminate and separable fastener. The present disclosure differs from this prior art disclosure in that the prior art disclosure does not teach the use of detachable adhesives to alternately attach sides of tabletops to table bases. This prior art disclosure is pertinent and may benefit from the devices disclosed herein and is hereby incorporated for reference in its entirety for all that it teaches.

### SUMMARY

A table comprising a table base and a tabletop is disclosed. The table base comprises a top surface comprising one or more removable adhesives. The one or more removable adhesives adhere strongly when a force is applied in a horizontal direction and weakly when a force is supplied in a vertical direction. This prevents horizontal movement but allows vertical movement when a vertical force above an adhesion threshold is applied. The tabletop comprises a usable first side and a usable second side alternately mounted to the table base by means of the removable adhesives.

The one or more removable adhesives may comprise adhesive agents that are removable from the first side, the second side, and the top surface without damage to the first side, the second side, or the top surface. The adhesion threshold may be below a weight of the table base such that the weight of the table base causes the tabletop to be removed when the tabletop is lifted. The adhesion threshold may be above a weight of the table base such that the table base must be held down while the tabletop is lifted and removed. The one or more removable adhesives may be reusable after removal. The adhesive agents may comprise polymer microfibers, polydimethysiloxane fibrils, collagen fibrils, or combinations thereof. The removable adhesives may prevent sliding in one direction and four portions of the removable adhesives may be oriented such that sliding is prevented in four directions, the directions forming an XY axis.

The table base may comprise one or more legs extending downward from the top surface with at least one of the one or more removable adhesives attached to the top surface above each of the one or more legs.

The tabletop may comprise an elevated pattern or patterns, a recessed pattern or patterns, or a combination thereof on the first side, the second side, or the first and the second side.

The first side may comprise a flush-mount touch screen computing device.

The first side may comprise a first smooth, uninterrupted surface and the second side may comprise a second smooth, uninterrupted surface.

The first side and the second side may comprise different materials. The first side and the second side may further comprise bamboo, hard wood, plywood, laminated plywood, laminates, rubber, vinyl, plastics, stainless steel, galvanized steel, carbon steel, black iron, pewter, copper, zinc, aluminum, glass, quartz, granite, marble, stone, ceramics, fiberboards, varnish, sealant, paint, or combinations thereof.

The table base may further comprise metal, wood, plastic, stone, glass, or combinations thereof.

The table may further comprise an electrical inlet or inlets, an electrical outlet or outlets, and an edge computer connection or connections in an edge or edges of the tabletop. The table may further comprise wiring passing through an interior portion of the tabletop between the edge computer connection or connections and a side computer connection or connections on the first side or the second side of the tabletop.

The first side may comprise a heating element or heating elements and the second side may comprise a cooling element or elements.

The first side and the second side may comprise different uses, the uses selected from the group consisting of computer usage, office work, drafting, art, cutting, metal working, working with tools, cooking, dining, gaming, conferencing, displaying, medical, massage, or combinations thereof.

### BRIEF DESCRIPTION OF THE DRAWINGS

In order that the advantages of the invention will be readily understood, a more particular description of the invention briefly described above will be rendered by reference to specific embodiments illustrated in the appended drawings. Understanding that these drawings depict only typical embodiments of the invention and are not therefore to be considered limiting of its scope, the invention will be described and explained with additional specificity and detail through use of the accompanying drawings, in which:

FIGS. 1A-B show an isometric view of a table and a side view of the table.

FIGS. 2A-C show isometric views of a table and a side view of the table.

FIGS. 3A-B show an isometric view of a table and a top view of one corner of the table.

FIGS. 4A-B show an isometric view of a table and a top view of one corner of the table.

FIGS. 5A-C show isometric views of a table and a side view of the table.

### DETAILED DESCRIPTION

It will be readily understood that the components of the present invention, as generally described and illustrated in the Figures herein, could be arranged and designed in a wide variety of different configurations. Thus, the following more detailed description of the embodiments of the invention, as represented in the Figures, is not intended to limit the scope of the invention, as claimed, but is merely representative of certain examples of presently contemplated embodiments in accordance with the invention.

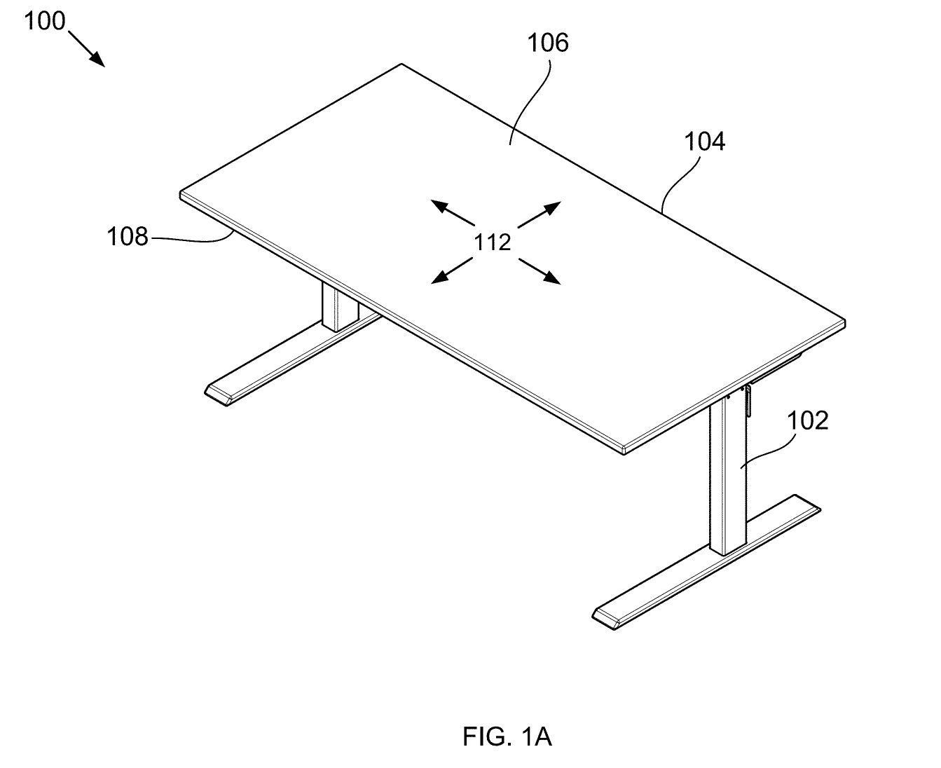

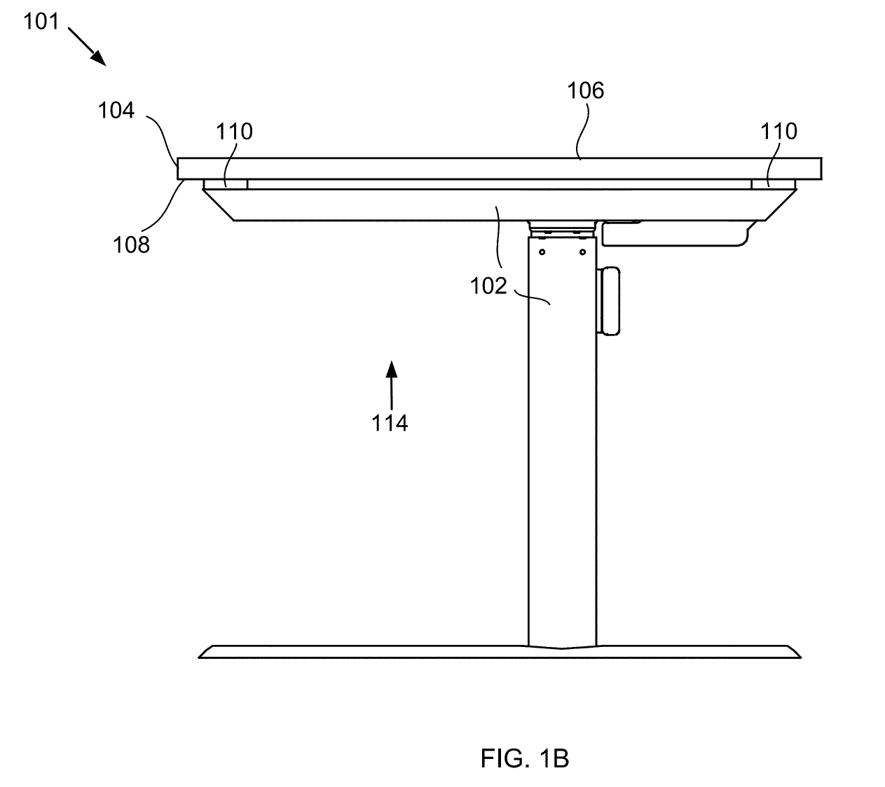

Referring to FIGS. 1A-B, an isometric view of a table is shown at 100 and a side view of the table is shown at 101, as per one embodiment of the present invention. A top surface of table base 102 is provided with removable adhesives 110. Tabletop 104 comprises first surface 106 and second surface 108. These surfaces are alternately mounted to table base 102 by means of removable adhesives 110. Removable adhesives 110 adhere strongly in horizontal plane 112, but weakly in vertical direction 114, such that the tabletop is removable by applying a vertical force above an adhesion threshold. This allows the use of the alternate side of tabletop 104. In some embodiments, the surfaces are both smooth and uninterrupted. In some embodiments, first surface 106 is metal and second surface 108 is bamboo. In other embodiments, first surface 106 is copper and second surface 108 is stainless steel. The size of removable adhesives 110 are exaggerated for clarity in the figure.

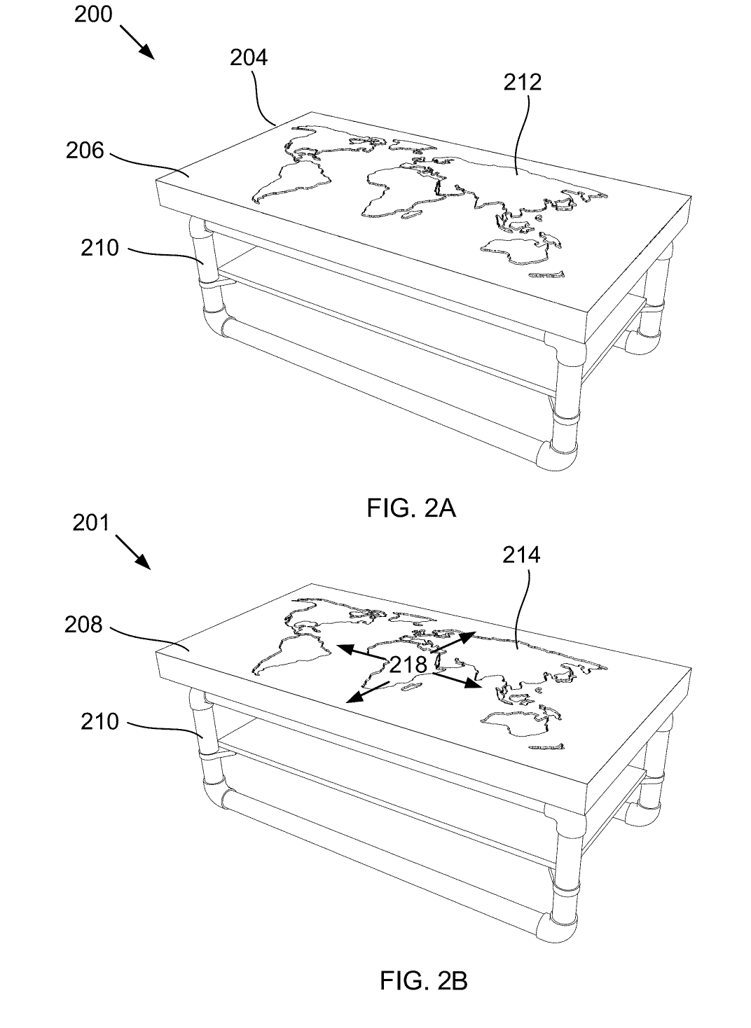

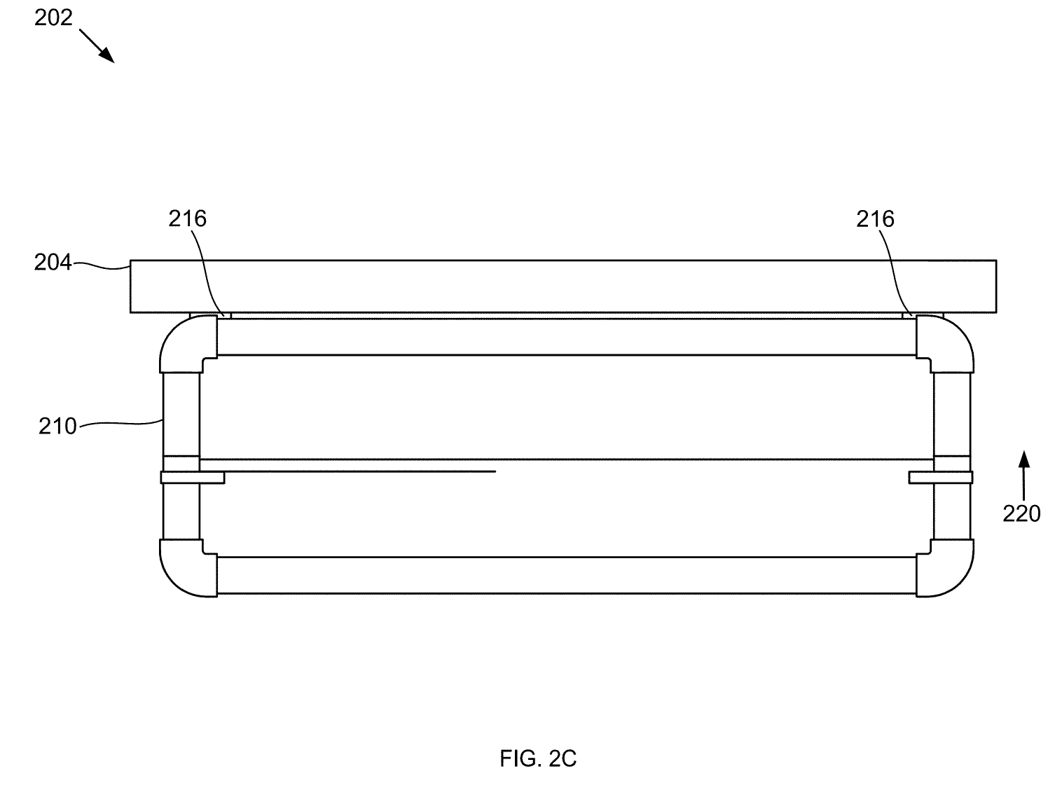

Referring to FIGS. 2A-C, isometric views of a table are shown at 200 and 201 and a side view of the table is shown at 202, as per one embodiment of the present invention. Top surfaces of table base 210 are provided with removable adhesives 210. Tabletop 204 comprises first surface 206 and second surface 208. These surfaces comprise raised relief map 212 and recessed map 214, respectively, and are alternately mounted to table base 210 by means of removable adhesives 216. Removable adhesives 216 adhere strongly in horizontal plane 218, but weakly in vertical direction 220, such that the tabletop is removable by applying a vertical force above an adhesion threshold. This allows the use of the alternate side of tabletop 204. Raised relief map 212 is not shown in side view 202 for clarity. The size of removable adhesives 216 are exaggerated for clarity in the figure.

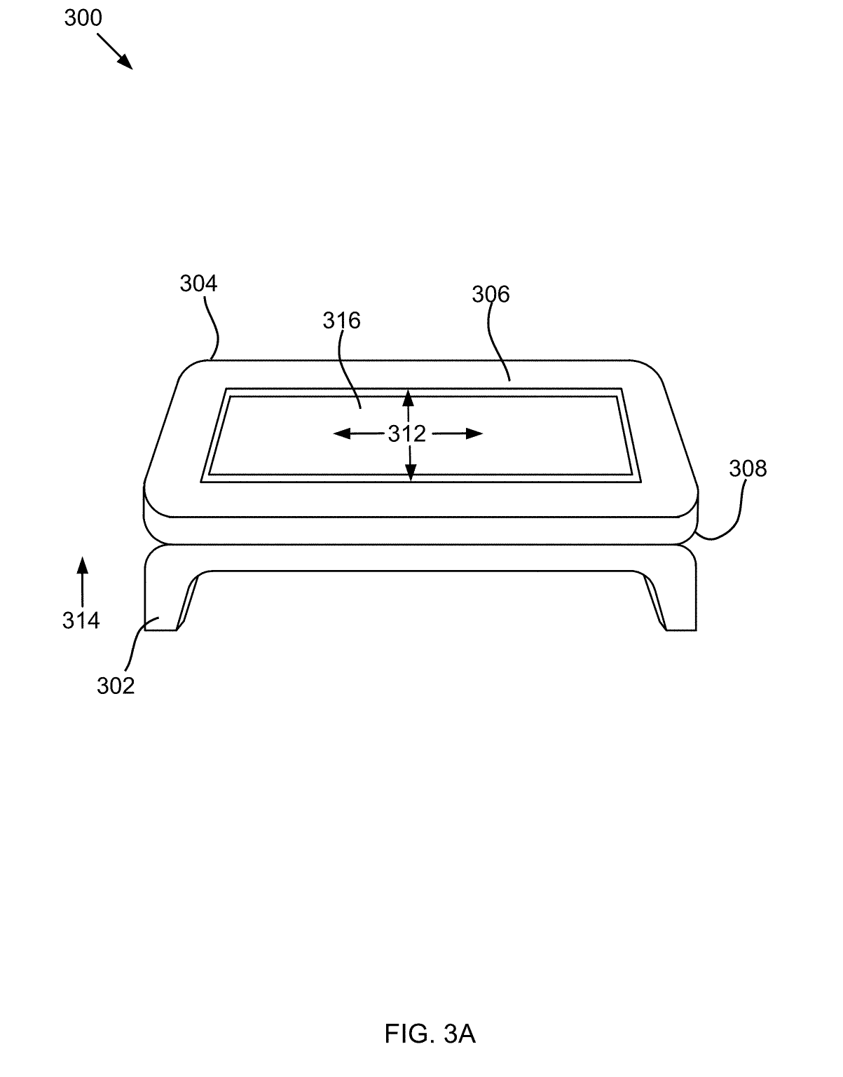

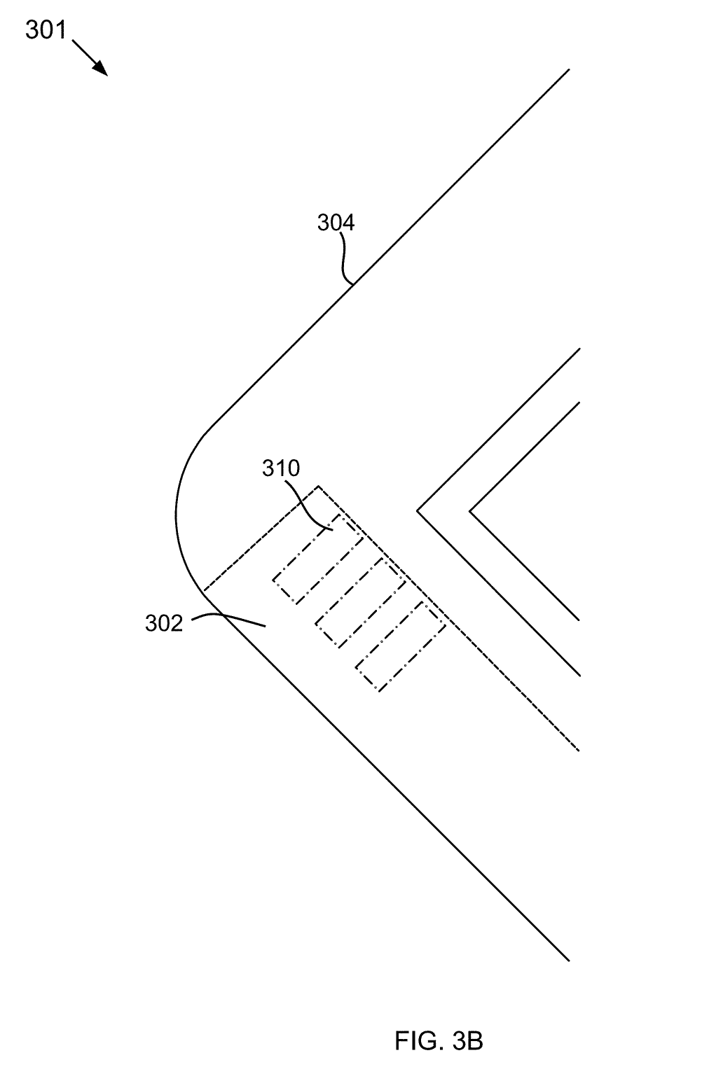

Referring to FIGS. 3A-B, an isometric view of a table is shown at 300 and a top view of one corner of the table is shown at 301, as per one embodiment of the present invention. A top surface of table base 302 is provided with removable adhesives 310. Tabletop 304 comprises first surface 306 and second surface 308. These surfaces are alternately mounted to table base 302 by means of removable adhesives 310. Removable adhesives 310 adhere strongly in horizontal plane 312, but weakly in vertical direction 314, such that the tabletop is removable by applying a vertical force above an adhesion threshold. This allows the use of the alternate side of tabletop 304. First surface 306 comprises flush-mount touchscreen computer monitor 316. Second surface 308 comprises a smooth, uninterrupted surface. In some embodiments, monitor 316 is an all-in-one, computer/monitor combination. In other embodiments, monitor 316 is a monitor requiring an external computer. In some embodiments, an edge of tabletop 304 contains inlets for electrical power as well as computer connections including USB, ethernet, HDMI, DisplayPort, and other standard computer ports. In some embodiments, an edge of tabletop 304 contains fans for removing heat from monitor 316.

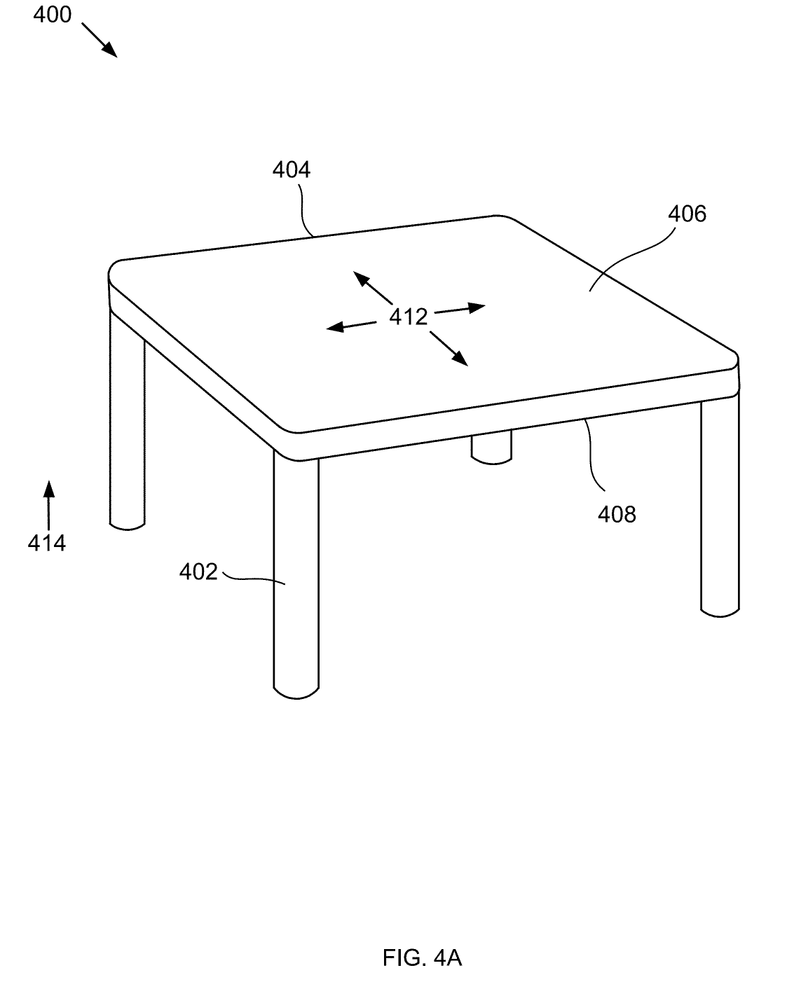

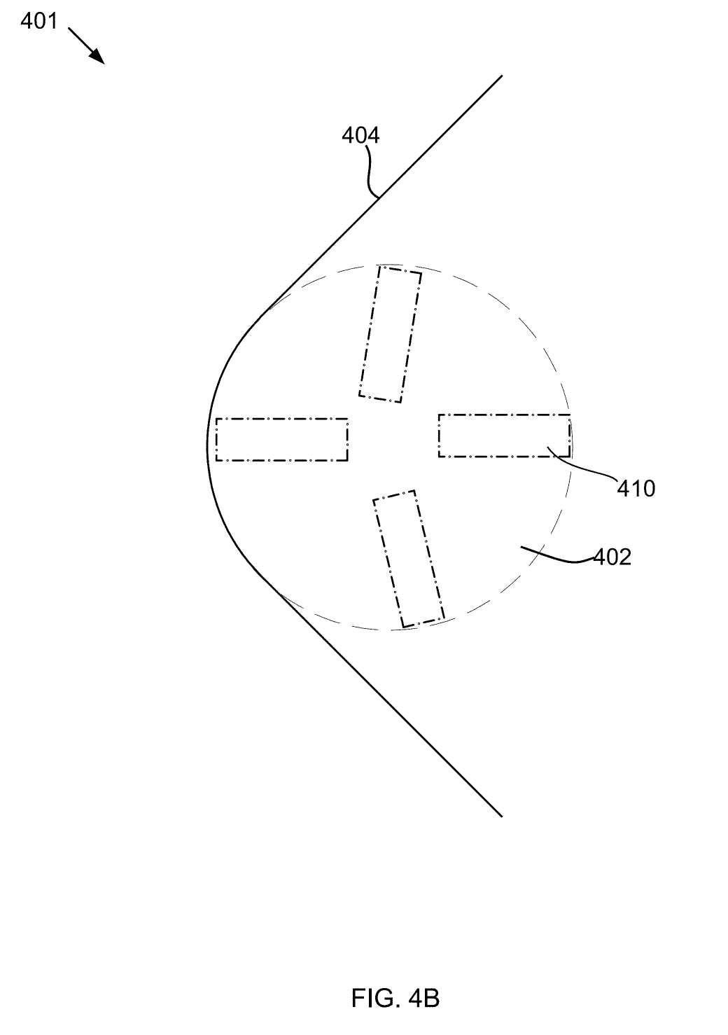

Referring to FIGS. 4A-B, an isometric view of a table is shown at 400 and a top view of one corner of the table is shown at 401, as per one embodiment of the present invention. A top surface of table legs 402 is provided with removable adhesives 410. Tabletop 404 comprises first surface 406 and second surface 408. These surfaces are alternately mounted to table legs 402 by means of removable adhesives 410. Removable adhesives 410 adhere strongly in horizontal plane 412, but weakly in vertical direction 414, such that the tabletop is removable by applying a vertical force above an adhesion threshold. This allows the use of the alternate side of tabletop 404. In some embodiments, first surface 406 and second surface 408 are different materials.

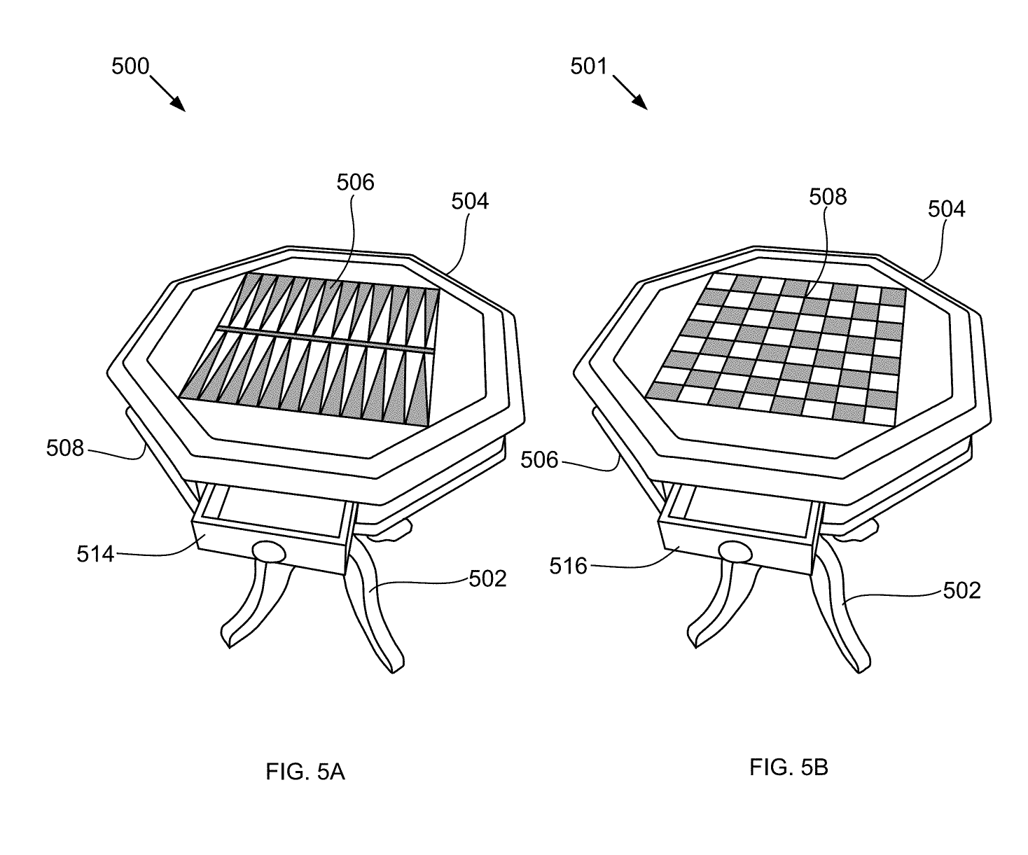

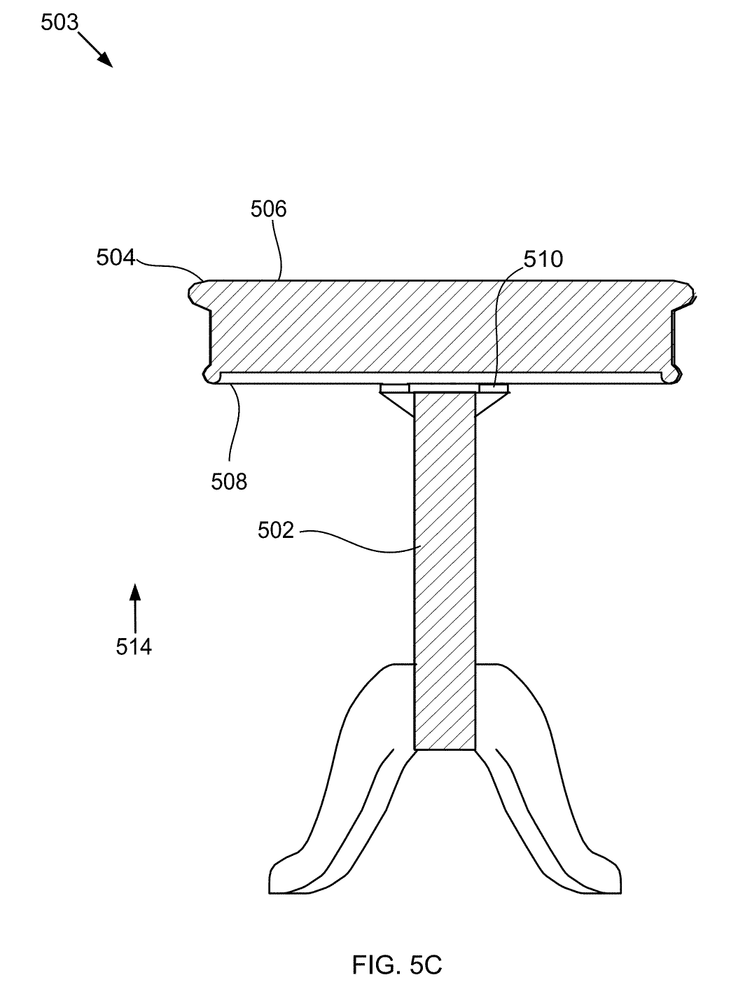

Referring to FIGS. 5A-C, isometric views of a table are shown at 500 and 501 and a side view of the table is shown at 503, as per one embodiment of the present invention. A top surface of table base 502 is provided with removable adhesives 510. Tabletop 504 comprises first surface 506 and second surface 508. These surfaces comprise backgammon and checkers, respectively, and are alternately mounted to table base 502 by means of removable adhesives 510. Removable adhesives 510 adhere strongly in the horizontal plane defined by the tabletop surfaces, but weakly in vertical direction 514, such that the tabletop is removable by applying a vertical force above an adhesion threshold. This allows the use of the alternate side of tabletop 504. Drawer 514 is blocked when first surface 506 is adhered to table base 502. Drawer 516 is blocked when second surface 508 is adhered to table base 502. In some embodiments, the adhesive agents used in removable adhesives 510 are removable from first surface 506, second surface 508, and the top surface of table base 502 without damage to any of the surfaces. The size of removable adhesives 510 are exaggerated for clarity in the figure.

In some embodiments, the one or more removable adhesives comprise adhesive agents that are removable from the first side, the second side, and the top surface without damage to the first side, the second side, or the top surface.

In some embodiments, the adhesion threshold is below a weight of the table base such that the weight of the table base causes the tabletop to be removed when the tabletop is lifted. In other embodiments, the adhesion threshold is above a weight of the table base such that the table base must be held down while the tabletop is lifted and removed

In some embodiments, the one or more removable adhesives are reusable after removal. In some embodiments, the adhesive agents comprise polymer microfibers, polydimethysiloxane fibrils, collagen fibrils, or combinations thereof. In some embodiments, the removable adhesives prevent sliding in one direction and four portions of the removable adhesives are oriented such that sliding is prevented in four directions, the directions forming an XY axis.

In some embodiments, the one or more removable adhesives comprise adhesive agents that are removable from the first side, the second side, and the top surface without damage to the first side, the second side, or the top surface.

In some embodiments, the table base comprises one or more legs extending downward from the top surface with at least one of the one or more removable adhesives attached to the top surface above each of the one or more legs.

In some embodiments, the tabletop comprises an elevated pattern or patterns, a recessed pattern or patterns, or a combination thereof on the first side, the second side, or the first and the second side.

In some embodiments, the first side comprises a flush-mount touch screen computing device.

In some embodiments, the first side comprises a first smooth, uninterrupted surface and the second side comprises a second smooth, uninterrupted surface.

In some embodiments, the first side and the second side comprise different materials. In some embodiments, the first side and the second side further comprise bamboo, hard wood, plywood, laminated plywood, laminates, rubber, vinyl, plastics, stainless steel, galvanized steel, carbon steel, black iron, pewter, copper, zinc, aluminum, glass, quartz, granite, marble, stone, ceramics, fiberboards, varnish, sealant, paint, or combinations thereof. In some embodiments, the table base further comprises metal, wood, plastic, stone, glass, or combinations thereof.

In some embodiments, the table further comprises an electrical inlet or inlets, an electrical outlet or outlets, and an edge computer connection or connections in an edge or edges of the tabletop. In some embodiments, the table further comprises wiring passing through an interior portion of the tabletop between the edge computer connection or connections and a side computer connection or connections on the first side or the second side of the tabletop.

In some embodiments, the first side comprises a heating element or heating elements and the second side comprises a cooling element or elements.

1. A table comprising:
a table base comprising a top surface comprising one or more removable adhesives;
the one or more removable adhesives adhering strongly when a force is applied in a horizontal direction and weakly when a force is supplied in a vertical direction, such that horizontal movement is prevented and vertical movement is possible when a vertical force above an adhesion threshold is applied;
a tabletop comprising a usable first side and a usable second side alternately mounted to the table base by means of the one or more removable adhesives.

2. The table of claim 1, wherein the one or more removable adhesives comprise adhesive agents that are removable from the first side, the second side, and the top surface without damage to the first side, the second side, or the top surface.

3. The table of claim 1, wherein the adhesion threshold is below a weight of the table base such that the weight of the table base causes the tabletop to be removed when the tabletop is lifted.

4. The table of claim 1, wherein the adhesion threshold is above a weight of the table base such that the table base must be held down while the tabletop is lifted and removed.

5. The table of claim 4, wherein the one or more removable adhesives are reusable after removal.

6. The table of claim 4, wherein the one or more removable adhesives comprise adhesive agents that are removable from the first side, the second side, and the top surface without damage to the first side, the second side, or the top surface.

7. The table of claim 6, wherein the adhesive agents comprise polymer microfibers, polydimethysiloxane fibrils, collagen fibrils, or combinations thereof.

8. The table of claim 7, wherein the removable adhesives prevent sliding in one direction and four portions of the removable adhesives are oriented such that sliding is prevented in four directions, the directions forming an XY axis.

9. The table of claim 1, wherein the table base comprises one or more legs extending downward from the top surface with at least one of the one or more removable adhesives attached to the top surface above each of the one or more legs.

10. The table of claim 1, wherein the tabletop comprises an elevated pattern or patterns, a recessed pattern or patterns, or a combination thereof on the first side, the second side, or the first and the second side.

11. The table of claim 1, wherein the first side comprises a flush-mount touch screen computing device.

12. The table of claim 1, wherein the first side comprises a first smooth, uninterrupted surface and the second side comprises a second smooth, uninterrupted surface.

13. The table of claim 1, wherein the first side and the second side comprise different materials.

14. The table of claim 13, wherein the first side and the second side further comprise bamboo, hard wood, plywood, laminated plywood, laminates, rubber, vinyl, plastics, stainless steel, galvanized steel, carbon steel, black iron, pewter, copper, zinc, aluminum, glass, quartz, granite, marble, stone, ceramics, fiberboards, varnish, sealant, paint, or combinations thereof.

15. The table of claim 1, wherein the table base further comprises metal, wood, plastic, stone, glass, or combinations thereof.

16. The table of claim 1, further comprising an electrical inlet or inlets, an electrical outlet or outlets, and an edge computer connection or connections in an edge or edges of the tabletop.

17. The table of claim 16, further comprising wiring passing through an interior portion of the tabletop between the edge computer connection or connections and a side computer connection or connections on the first side or the second side of the tabletop.

18. The table of claim 1, wherein the first side comprises a heating element or heating elements and the second side comprises a cooling element or elements.

19. The table of claim 1, wherein the first side and the second side comprise different uses, the uses selected from the group consisting of computer usage, office work, drafting, art, cutting, metal working, working with tools, cooking, dining, gaming, conferencing, displaying, medical, massage, or combinations thereof.

20. A table comprising:
a table base comprising a top surface comprising one or more removable adhesives and, metal, wood, plastic, stone, glass, or combinations thereof;
the one or more removable adhesives adhering strongly when a force is applied in a horizontal direction and weakly when a force is supplied in a vertical direction, such that horizontal movement is prevented and vertical movement is possible when a vertical force above an adhesion threshold is applied, wherein:
the one or more removable adhesives comprise adhesive agents that are removable from the first side, the second side, and the top surface without damage to the first side, the second side, or the top surface;
the adhesion threshold is below a weight of the table base such that the weight of the table base causes the tabletop to be removed when the tabletop is lifted; and,
the one or more removable adhesives are reusable after removal; and,
a tabletop comprising a usable first side and a usable second side alternately mounted to the table base by means of the removable adhesives, wherein:
the first side and the second side comprise different materials; and,
the first side and the second side further comprise bamboo, hard wood, plywood, laminated plywood, laminates, rubber, vinyl, plastics, stainless steel, galvanized steel, carbon steel, black iron, pewter, copper, zinc, aluminum, glass, quartz, granite, marble, stone, ceramics, fiberboards, varnish, sealant, paint, or combinations thereof.
